(19) United States
(12) Patent Application Publication
(10) Pub. No.: US 2012/0020039 A1
(43) Pub. Date: Jan. 26, 2012

(54) SURFACE-MOUNTED SHIELDED MULTICOMPONENT ASSEMBLY

(75) Inventors: Romain Coffy, Saint Martin le Vinoux (FR); Jean-François Sauty, Saint Egreve (FR)

(73) Assignee: STMICROELECTRONICS (GRENOBLE) SAS, Grenoble (FR)

(21) Appl. No.: 13/163,533

(22) Filed: Jun. 17, 2011

Related U.S. Application Data
(63) Continuation-in-part of application No. PCT/EP2009/006641, filed on Dec. 4, 2009.

(30) Foreign Application Priority Data
Dec. 19, 2008 (FR) 08 58844

(51) Int. Cl. H05K 7/02; H05K 3/00; H05K 9/00

(52) U.S. Cl. 361/760; 174/388; 174/390; 29/829

(57) ABSTRACT

A surface-mounted shielded multicomponent assembly, comprising a wafer on which several electronic components are assembled; an insulating layer conformally deposited on the structure with a thickness smaller than the height of the electronic components, comprising at least one opening emerging on a contact of said wafer; a conductive shielding layer covering the insulating layer and said at least one opening; and a resin layer covering the conductive layer.

### BACKGROUND

1. Technical Field

The present disclosure relates to a surface-mounted multicomponent assembly and, more specifically, to such a multicomponent assembly provided with a shielding.

2. Description of the Related Art

Conventionally, electronic component manufacturers market individual components in the form of bare chips, or most often of packaged chips. Then, these components, be they discrete or integrated, are assembled by assemblers on large printed circuit boards on which they can be interconnected. In the last years, electronic component manufacturers have also marketed surface-mounted multicomponent assemblies in a single package.

As illustrated in FIG. 1, such multicomponent assemblies are currently formed on a support 1 such as a flexible printed circuit board. This support has the shape of a strip and several active or passive components 2, 3, 4 are successively mounted on the strip and connected to pads arranged on the upper side of the strip. In the shown example, component 3 is a bare integrated circuit chip, itself assembled by surface-mounting on strip 1. Once the components have been arranged, the assembly is covered with a protection resin layer 6, and contact balls 8 for a surface mounting are arranged on the lower surface side of the strip, one or several balls being connected to one or several pads of the upper surface of the strip, that is, to one or several terminals of the components assembled on the strip. Then, each component assembly protected by the resin layer is cut, along scribe lines 9, to form individual multicomponent packages. It should be noted that the representation of FIG. 1 is not to scale and has been significantly enlarged in the vertical direction to show the succession of multicomponent assemblies formed on a strip.

FIG. 2 shows such a multicomponent package 10 assembled by an assembler on a printed circuit board 11, it being understood that this printed circuit board supports many other components or multicomponent assemblies. Printed circuit board 11, in the same way as board 1, generally is a multiple-layer board to favor connections between terminals. In many cases, especially when the multicomponent package comprises high-frequency components, or on the contrary when it comprises elements to be protected against high-frequency noise from neighboring components, the installer must shield the multicomponent package. For this purpose, a metal cap 12 is assembled on board 11 above the multicomponent package, this cap being grounded via a pad 14 formed on the upper surface of board 11, the pad being possibly connected to a ground grid arranged under the multicomponent, possibly in an intermediary layer of board 11 if it is a multiple-layer board.

This assembly operation is complex, expensive, and takes time. Component assemblers would thus like component manufacturers to be able to provide them with shielded multicomponents, the shielding being connected to a connection to be grounded.

On the other hand, electronic component manufacturers would like to minimize the number of manufacturing operations and their complexity to avoid too significant an increase of the cost of their component.

### BRIEF SUMMARY

One embodiment of the present disclosure is a shielded multicomponent package which solves the disadvantages of prior art and, in particular, which does not excessively complicates the manufacturing, which can have a low cost, and which is reliable.

One embodiment of the present disclosure provides a surface-mounted shielded multicomponent assembly, comprising a wafer on which several electronic components are assembled; an insulating layer conformally deposited on the structure with a thickness smaller than the height of the electronic components, comprising at least one opening emerging on a contact of said wafer; a conductive shielding layer covering the insulating layer and said at least one opening; and a resin layer covering the conductive layer.

According to an embodiment of the present disclosure, the conductive shielding layer is provided with grooves.

According to an embodiment of the present disclosure, the conductive shielding layer comprises at least two metal layers, respectively made of titanium-tungsten and of copper.

According to an embodiment of the present disclosure, the insulating layer is made of a carbon polymer.

According to an embodiment of the present disclosure, said wafer is a printed circuit board portion comprising pads of contact with the components on its upper surface side, contact balls on its lower surface side, and means of connection between the pads and the balls.

An embodiment of the present disclosure provides a method for forming a surface-mounted shielded multicomponent assembly in which several packages are formed by collective operations on a strip-shaped wafer and then cut into individual chips.

The foregoing features, and advantages of the present disclosure will be discussed in detail in the following non-limiting description of specific embodiments in connection with the accompanying drawings.

### BRIEF DESCRIPTION OF THE SEVERAL VIEWS OF THE DRAWINGS

FIG. 1, previously described, shown a multicomponent package manufacturing chip;

FIG. 2, previously described, shows a shielded multicomponent package assembly on a printed circuit board;

FIG. 3 shows an example of a shielded multicomponent package; and

FIG. 4 shows an example of a shielded multicomponent package according to an embodiment of the present disclosure.

### DETAILED DESCRIPTION

For clarity, the same elements have been designated with the same reference numerals in the different drawings and, further, as usual in the representation of microelectronics components, the various drawings are not to scale.

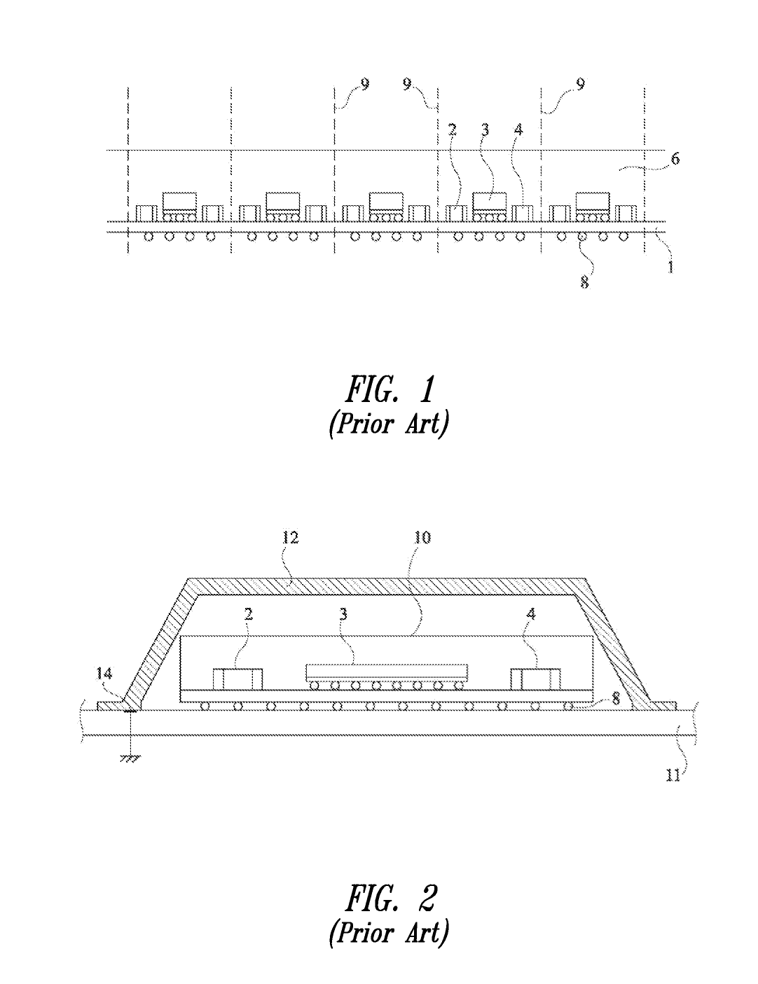

FIG. 3 shows a shielded multicomponent package before cutting, still in the form of a strip. Three components 2, 3, 4 are assembled on a wafer intended for a surface mounting and coated with a resin layer 6 in the same way as described in relation with FIG. 1. To shield the structure, a conductive layer 20 is deposited on its surface. However, a difficulty arises to ground shielding layer 20 if this connection is desired to be performed before cutting of the strip into individual packages. A solution comprises, as shown, before depositing metal layer 20, making a scribe line 21 through resin 6 opposite to a pad 22 of printed circuit board 1 connected to a ball 23 intended to be grounded. Thus, when conductive layer 20 is deposited, it forms on the one hand at the surface, and on the other hand by filling scribe line 21.

The multicomponent package shown in FIG. 3 is compatible with the forming of a multicomponent assembly on a support strip, but has disadvantages. On the one hand, scribe line 21 is made, which is an additional operation with respect to the operations usually performed. Further, the component ends up with a metalized upper surface, which is unusual. Indeed, manufacturers and users prefer to have an upper surface formed of the upper surface of an insulating resin layer, which may in particular be marked. To have an upper resin surface, the steps of performing a first resin deposition, of making scribe line 21, and of performing a conductive deposition should be carried out and followed by the deposition of a second resin layer thickness. This also complicates the manufacturing process.

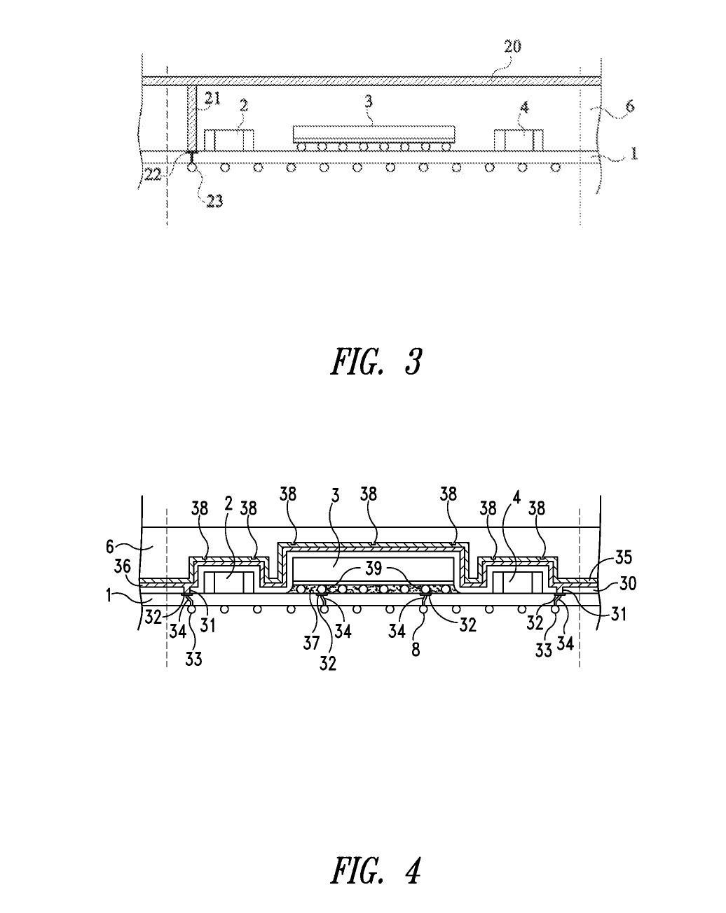

FIG. 4 shows a strip, preferably flexible, for example, a multiple-layer printed circuit board, supporting electronic components 2, 3, 4.

An insulating layer 30, for example, a layer deposited by spraying and annealed to remove the solvent, is deposited on this component assembly. A plasma deposition of a material such as carbon polymer may also be performed. This insulating layer is provided with openings 31 that open to respective contact pads 32 on the upper surface of support wafer 1, these pads being connected by metallizations 34 internal to the support wafer to respective connection balls 33. The opening sin the insulating layer may be formed by using a simple mask. A laser drilling may also be performed. This insulating layer 30 will for example have a thickness ranging from 5 to 15 micrometers, although this is not critical. This thickness is anyways selected to be much smaller than the heights of electronic components 2, 3, 4.

After this, a metal layer 35 is deposited over the entire structure and is used as a shield layer. Conventionally, a conductive bonding layer 36, for example, made of TiW may be deposited by spraying. This spraying may be followed by an electrodeposition of copper of a thickness of a few micrometers, for example, from 3 to 10 micrometers to form the metal layer 35. Then, conventionally, a resin layer 6 is deposited.

An advantage of depositing insulating layer 30 by spraying is that such a deposition is conformal, that is, this layer is present on the side and on top of the various components. Another advantage is that a removal of this insulating layer at the level of a contact pad may be performed very simply. This insulating layer has, as indicated, a thickness from 5 to 15 microns so that, between electronic components 2-4, conductive layer 35, 36 is placed opposite to the most part of the component side. Thus, the shielding function of conductive layer 35, 36 is effective not only between the components and the outside, but also between components of a same package.

In a usual manufacturing process, after the encapsulation with resin 6, solder balls 8 are deposited on the lower surface of the board 1, but this is just a possible variation. The solder balls 8 may be connected by additional metallizations 34 through the board 1 to additional contact pads 32 that are coupled by further solder balls 39 to at least one of the electronic components 2, 3, and 4.

A material 37 arranged under the electronic component to avoid for air bubbles to remain after the resin has been arranged has also been shown in the drawing. This material under the component is a conventionally arranged liquid resin.

Specific embodiments of the present disclosure have been described. Various alterations and modifications will occur to those skilled in the art, in particular as concerns the selection of the materials of insulating layer 30 and of conductive layer 35, as well as their deposition mode. Various measures may also be taken to increase the bonding between layers, for example, to groove the upper surface of conductive layer 35 with grooves 38.

Various embodiments with different variations have been described hereabove. It should be noted that those skilled in the art may combine various elements of these various embodiments and variations together and with known elements and techniques without any inventive step being involved.

Such alterations, modifications, and improvements are intended to be part of this disclosure, and are intended to be within the spirit and the scope of the present disclosure. Accordingly, the foregoing description is by way of example only and is not intended to be limiting. The present disclosure is limited only as defined in the following claims and the equivalents thereto.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A surface-mounted shielded multicomponent assembly, comprising:
a substrate;
a conductive contact on the substrate;
plural electronic components assembled on the substrate;
a conformal insulating layer on the electronic components and having a thickness smaller than a height of the electronic components, the conformal insulating layer including an opening emerging on the conductive contact;
a conductive shielding layer covering the insulating layer and extending in said opening; and
a resin layer covering the conductive layer.

2. The assembly of claim 1, wherein the conductive shielding layer is provided with grooves.

3. The assembly of claim 1, wherein the conductive shielding layer comprises at least two metal layers, respectively made of titanium-tungsten and of copper.

4. The assembly of claim 1, wherein the insulating layer is made of a carbon polymer.

5. The assembly of claim 1, wherein said substrate is a printed circuit board portion having a lower surface side, an upper surface side, a contact pad on the upper surface side and coupled with at least one of the components, a contact ball on the lower surface side, and a conductive connection between the contact pad and the contact ball.

6. The assembly of claim 1, wherein said substrate is a printed circuit board portion having a lower surface side, an upper surface side on which the conductive contact is positioned, a contact ball on the lower surface side, and a conductive connection between the conductive contact and the contact ball.

7. The assembly of claim 1 wherein the electronic components include first and second electronic components spaced apart from each other by a gap and the insulating layer and shielding layer both extend in the gap between the first and second electronic components.

8. A method for forming a shielded multicomponent assembly, comprising:
mounting first and second electronic components mounted on a substrate;
conformally depositing an insulating layer on the first and second electronic components;
forming a first opening through the insulating layer;
conformally applying a conductive shielding layer on the deposited insulating layer and in the first opening; and
covering the conductive shielding layer with a resin layer.

9. The method of claim 8, further comprising cutting grooves into the conductive shielding layer prior to covering the conductive shielding layer with the resin layer.

10. The method of claim 8, further comprising:
mounting third and fourth electronic components on the substrate, wherein the depositing includes conformally depositing the insulating layer on the third and fourth electronic components;
forming a second opening through the insulating layer, wherein the applying includes applying the conductive shielding layer on the deposited insulating layer and in the second opening and the covering includes covering the shielding layer and the third and fourth electronic components with the resin layer; and
forming a plurality of individual shielded electronic assemblies by cutting though the substrate and the insulating, shielding, and resin layers.

11. The method of claim 8, wherein the conductive shielding layer comprises first and second metal layers.

12. The method of claim 11, wherein the applying includes spraying the first metal layer on the insulating layer and in the opening and electrodepositing the second metal layer on the first metal layer.

13. A surface-mounted shielded multicomponent assembly, comprising:
a substrate;
plural electronic components assembled on the substrate;
a conformal insulating layer on the electronic components and having a thickness smaller than a height of the electronic components;
a conformal, conductive shielding layer covering the insulating layer; and
a resin layer covering the conductive layer.

14. The assembly of claim 13, wherein the conductive shielding layer includes grooves and the resin layer extends within the grooves.

15. The assembly of claim 13, wherein the conductive shielding layer comprises at least two metal layers.

16. The assembly of claim 13, wherein the insulating layer is made of a carbon polymer.

17. The assembly of claim 13, wherein said substrate is a printed circuit board portion having a lower surface side, an upper surface side, a contact pad on the upper surface side and coupled with at least one of the components, a contact ball on the lower surface side, and a conductive connection between the contact pad and the contact ball.

18. The assembly of claim 13, wherein said substrate is a printed circuit board portion having a lower surface side, an upper surface side, a conductive contact coupled to the conductive shielding layer, a contact ball on the lower surface side, and a conductive connection between the conductive contact and the contact ball.

19. The assembly of claim 13 wherein the electronic components include first and second electronic components spaced apart from each other by a gap and the insulating layer and shielding layer both extend in the gap between the first and second electronic components.
